(19) United States
(12) Patent Application Publication
(10) Pub. No.: US 2019/0267402 A1
(43) Pub. Date: Aug. 29, 2019

(54) ARRAY SUBSTRATE AND MANUFACTURING METHOD FOR THE SAME

(71) Applicant: SHENZHEN CHINA STAR OPTOELECTRONICS SEMICONDUCTOR DISPLAY TECHNOLOGY CO., LTD., Shenzhen (CN)

(72) Inventor: Jianmin ZHANG, Shenzhen (CN)

(21) Appl. No.: 16/174,806

(22) Filed: Oct. 30, 2018

Related U.S. Application Data
(63) Continuation of application No. PCT/CN2018/083920, filed on Apr. 20, 2018.

(30) Foreign Application Priority Data
Feb. 26, 2018 (CN) 201810160337.7

(51) Int. Cl. H01L 27/12; H01L 29/423

(52) U.S. Cl. CPC H01L 27/124; H01L 29/42384; H01L 27/127

(57) ABSTRACT

An array substrate and manufacturing method are disclosed. Through forming a first source-drain layer between the base substrate and the semiconductor material layer, and performing a heat treatment to the semiconductor material layer such that a material of the first source-drain layer is diffused into the semiconductor material layer such that a region of the semiconductor material layer corresponding to the first source-drain layer becomes conductive. The obtained semiconductor layer includes a semiconductor region, and a first conductive region and a second conductive region located on both sides of the semiconductor region. The first source-drain material is diffused into the semiconductor layer by the heat treatment, the oxygen content in the semiconductor layer is redistributed so as to obtain the first conductive region and the second conductive region. The present invention has a good thermal stability, ensuring the carrier transmission and the electrical properties of the thin film transistor.

### CROSS REFERENCE

This application is a continuing application of PCT Patent Application No. PCT/CN2018/083920, entitled “ARRAY SUBSTRATE AND MANUFACTURING METHOD FOR THE SAME”, filed on Apr. 20, 2018, which claims priority to China Patent Application No. CN 201810160337.7 filed on Feb. 26, 2018, both of which are hereby incorporated in its entireties by reference.

### FIELD OF THE INVENTION

The present invention to a display technology field, and more particularly to an array substrate and a manufacturing method for an array substrate.

### BACKGROUND OF THE INVENTION

A top-gate array substrate has advantages of small parasitic capacitance, few masks and high reliability so that the top-gate array substrate has been widely used. When fabricating the top-gate array substrate, a plasma (Ar, He, Nz, etc.) is usually used to perform a conductive treatment on the position where the semiconductor layer is in contact with the source/drain electrodes in order to reduce the contact resistance between the source/drain electrodes and the semiconductor layer. However, during the subsequent annealing, the contact resistance between the source/drain electrodes and the semiconductor layer is gradually recovered to be larger, affecting the carrier transmission, and ultimately affecting the electrical properties of the thin film transistor.

### SUMMARY OF THE INVENTION

The present invention provides an array substrate and a manufacturing method for an array substrate, which can reduce the contact resistance between the source/drain electrodes and the semiconductor layer, ensure the carrier transmission in order to ensure the electrical properties of the thin film transistor.

The array substrate, comprising: a base substrate; a first source-drain layer, a semiconductor layer, gate insulation layer, a gate layer, interlayer dielectric layer, and a second source-drain layer which are sequentially stacked on the base substrate; wherein the first source-drain layer includes a first source electrode and a first drain electrode which are disposed separately; wherein the semiconductor layer includes a semiconductor region, a first conductive region, and a second conductive region; the first conductive region and the second conductive region are respectively located at two sides of the semiconductor region and are connected to the semiconductor region; the first conductive region is stacked on the first source electrode, and the second conductive region is stacked on the first drain electrode; the first conductive region and the second conductive region are both obtained by diffusing a material of the first source-drain layer into the semiconductor layer; wherein the second source-drain layer includes a second source electrode and a second drain electrode which are disposed separately; and wherein the second source electrode is electrically connected to the first source electrode through a first via; the second drain electrode is electrically connected to the first drain electrode through a second via.

Wherein the first conductive region partially covers the first source electrode, and the second conductive region partially covers the first drain electrode; the first via corresponds to a portion of the first conductive region and a portion of the first source electrode not covered by the first conductive region; the second via corresponds to a portion of the second conductive region and a portion of the first drain electrode not covered by the second conductive region.

Wherein the first conductive region partially covers the first source electrode, and the second conductive region partially covers the first drain electrode; the first via corresponds to a location of the first conductive region not covered by the first source electrode, and the second via corresponds to a location of the second conductive region not covered by the first drain electrode.

Wherein the gate layer includes a gate electrode, the gate electrode layer is stacked on the gate insulation layer, and an orthographic projection of the gate insulation layer and the gate electrode on the semiconductor layer is located within the semiconductor region.

Wherein the material of the first source-drain layer is a metal material having a work function less than 4.4 ev and a resistivity less than 10⁻⁷ Ω·m.

Wherein the material of the second source-drain layer is aluminum.

The manufacturing method for an array substrate, comprising steps of: providing a base substrate, and forming a first source-drain layer on the base substrate, wherein the first source-drain layer includes a first source electrode and a first drain electrode disposed separately; forming a semiconductor material layer on the first source-drain layer, performing a heat treatment to the semiconductor material layer such that a material of the first source-drain layer is diffused into a region of the semiconductor material layer corresponding to the first source-drain layer, and the region of the semiconductor material layer corresponding to the first source-drain layer becomes conductive; patterning the semiconductor material layer to obtain a semiconductor layer, wherein the semiconductor layer includes a semiconductor region, a first conductive region and a second conductive region, the first conductive region and the second conductive region are located at two sides of the semiconductor region and are respectively connected to the semiconductor region, the first conductive region is stacked on the first source electrode, and the second conductive region is stacked on the first drain electrode; sequentially forming a gate insulation layer, a gate layer, and an interlayer dielectric layer on the semiconductor layer; forming a second source-drain layer on the interlayer dielectric layer, wherein the second source-drain layer includes a second source electrode and a second drain electrode which are disposed separately, the second source electrode is electrically connected to the first source electrode through a first via; the second drain electrode is electrically connected to the first drain electrode through a second via.

Wherein the method further comprises steps of: forming a passivation layer on the second source-drain layer, and forming a pixel electrode layer on the passivation layer, wherein the pixel electrode layer includes multiple pixel electrodes arranged as a matrix, and the pixel electrode is electrically connected to the second source-drain layer through a via.

Wherein the step of performing a heat treatment to the semiconductor material layer is to perform an annealing treatment to the semiconductor material layer.

Wherein the material of the first source-drain layer is a metal material having a work function less than 4.4 ev and a resistivity less than 10⁻⁷ Ω·m.

In the array substrate and the manufacturing method for the array substrate provided in the present invention, through forming a first source-drain layer between the base substrate and the semiconductor material layer, and performing a heat treatment to the semiconductor material layer before patterning the semiconductor material layer such that a material of the first source-drain layer is diffused into a region of the semiconductor material layer, and the oxygen content in the semiconductor material layer is redistributed such that a region of the semiconductor material layer corresponding to the first source-drain layer becomes conductive in order to obtain a first conductive region and a second conductive region. The first conductive region and the second conductive region have a good thermal stability, without being affected by subsequent heat treatment. Besides, the first conductive region is stacked on the first source electrode, and the second conductive region is stacked on the first drain electrode, that is, the first conductive region is electrically connected to the first source electrode, and the second conductive region is electrically connected to the first drain electrode. When the second source electrode is electrically connected to the first source electrode, that is, the second source electrode is electrically connected to the first conductive region of the semiconductor layer through the first source electrode; When the second drain electrode is electrically connected to the first drain electrode, that is, the second drain electrode is electrically connected to the second conductive region of the semiconductor layer through the first drain electrode. Both the first conductive region and the second conductive region become conductive and are not affected by the subsequent heat treatment process, so that the contact resistance between the source and drain electrodes and the semiconductor layer is reduced, and The contact resistance is not affected by the subsequent heat treatment process so as to ensure carrier transport and ensure the electrical properties of the thin film transistor.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a schematic diagram of an array substrate according to an embodiment of the present invention;

FIG. 2 is a schematic diagram of an array substrate according to another embodiment of the present invention;

FIG. 3 is a schematic diagram of an array substrate according to another embodiment of the present invention;

FIG. 4 is a flow chart of a manufacturing method for an array substrate according to the present invention; and

FIG. 5-FIG. 10 are schematic diagrams of steps of the manufacturing method for an array substrate according to the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention. The patterned patterning process described herein includes patterning, developing, exposing, etching, and other patterning processes.

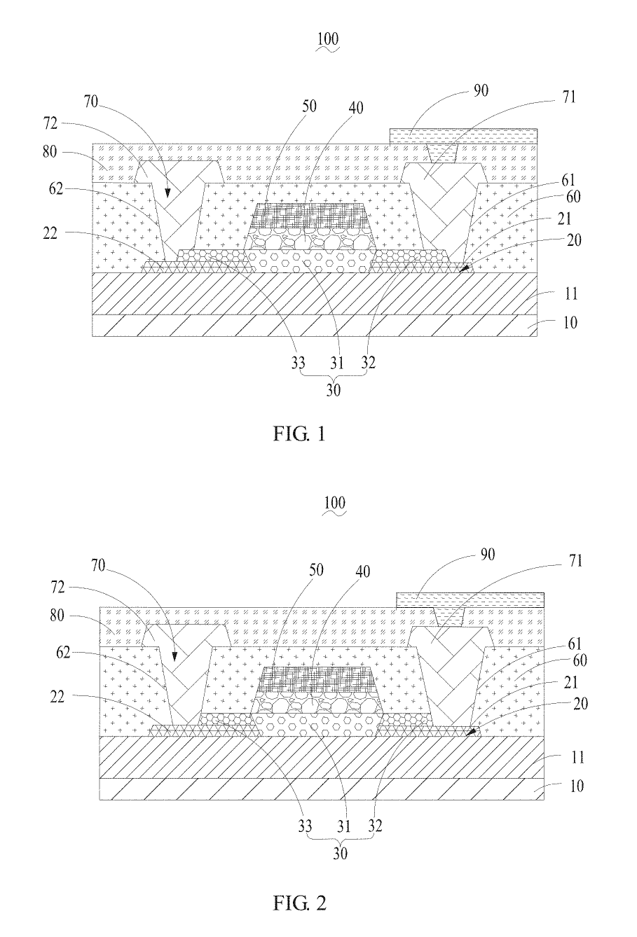

With reference to FIG. 1, the present invention provides with an array substrate 100. The array substrate 100 includes a base substrate 10, and a first source-drain layer 20, a semiconductor layer 30, gate insulation layer 40, a gate layer 50, interlayer dielectric layer 60, and a second source-drain layer 70 which are sequentially stacked on the base substrate 10. Furthermore, a buffer layer 11 is further provided between the base substrate 10 and the first source-drain layer 20, and the buffer layer 11 reinforces a combination effect between the first source-drain layer 20 and the base substrate 10.

The first source-drain layer 20 includes a first source electrode 21 and a first drain electrode 22 which are disposed separately. In the present invention, the material of the first source-drain layer 20 is a metal material having a low work function and low resistivity in order to make the material of the first source-drain layer 20 to be easily diffused into the semiconductor layer 30 during the subsequent heat treatment, and the semiconductor layer 30 can be conductive. Specifically, the material of the first source-drain layer 20 is a metal material having a work function less than 4.4 ev and a resistivity less than 10⁻⁷ Ω·m. In this embodiment, the first source-drain layer 20 is metal aluminum. It can be understood that the first source-drain layer 20 may be metal silver or other metal material having a low work function and low resistivity.

The semiconductor layer 30 includes a semiconductor region 31, a first conductive region 32, and a second conductive region 33. The first conductive region 32 and the second conductive region 33 are respectively located at two sides of the semiconductor region 31 and are connected to the semiconductor region 31. The first conductive region 32 is stacked on the first source electrode 21, and the second conductive region 33 is stacked on the first drain electrode 22. The first conductive region 32 and the second conductive region 33 are both obtained by diffusing the material of the first source-drain layer 20 into the semiconductor layer 30, and making the oxygen content in the semiconductor layer 30 to be re-arranged. The first conductive region 32 and the second conductive region 33 obtained by the above way has a good thermal stability and do not generate a change in the conductivity during the subsequent heat treatment.

In this embodiment, the first conductive region 32 partially covers the first source electrode 21, and the second conductive region 33 partially covers the first drain electrode 22. In addition, the semiconductor region 31 is located between the first source electrode 21 and the first drain electrode 22. That is, the semiconductor region 31 covers a portion of the substrate 10 that is located between the first source electrode 21 and the second drain electrode and not covered by the first source-drain layer 20. It can be understood that in another embodiment of the present invention, the first conductive region 32 covers the first source electrode 21, and the second conductive region 33 covers the second source electrode 71.

The gate insulation layer 40 is located between the semiconductor layer 30 and the gate layer 50. The semiconductor layer 30 and the gate layer 50 are separated by the gate insulation layer 40. The gate layer 50 includes a gate electrode. The gate electrode layer 50 is stacked on the gate insulation layer 40, and an orthographic projection of the gate insulation layer 40 and the gate electrode on the semiconductor layer 30 is located within the semiconductor region 31.

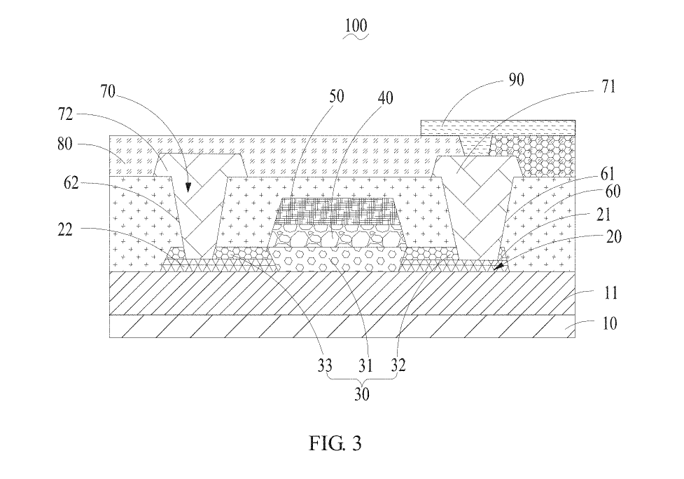

The interlayer dielectric layer 60 is stacked on the gate layer 50 and covers the gate layer 50, the semiconductor layer 30 not covered by the gate layer 50, the first source-drain layer 20 not covered by the semiconductor layer 30 and the substrate 10 not covered by the first source-drain layer 20. The interlayer dielectric layer 60 is formed by an insulation material to separate the gate layer 50 from other layer structures. The interlayer dielectric layer 60 is provided with a first via 61 and a second via 62. In this embodiment, the first via 61 corresponds to a portion of the first conductive region 32 and a portion of the first source electrode 21 not covered by the first conductive region 32; the second via 62 corresponds to a portion of the second conductive region 33 and a portion of the first drain electrode 22 not covered by the second conductive region 33. It can be understood that, in other embodiments of the present invention, with reference to FIG. 2, the first via 61 only corresponds to the first source electrode 21, and the second via 62 only corresponds to the first drain electrode 22. Alternatively, with reference to FIG. 3, the first via 61 extends to the first source electrode 21 through the first conductive region 32, and the second via 62 extends to the first drain electrode 22 through the second conductive region 33.

The second source-drain layer 70 is disposed on the interlayer dielectric layer 60 and including a second source electrode 71 and a second drain electrode 72. The second source electrode 71 is electrically connected to the first source electrode 21 through the first via 61, and the second drain electrode 72 is electrically connected to the first drain electrode 22 through the second via 62. That is, the second source electrode 71 is electrically connected to the first conductive region 32 of the semiconductor layer 30 through the first source electrode 21; that is, the second drain electrode 72 passes through the first drain electrode 22 to electrically connect to the second conductive region 33 of the semiconductor layer 30. The semiconductor layer 30 and the first drain electrode 22 realize a data signal transmitted between the second source electrode 71 and the second drain electrode 72. In this embodiment, the first via 61 corresponds to a portion of the first conductive region 32 and a portion of the first source electrode 21 not covered by the first conductive region 32; the second via 62 corresponds to a portion of the second conductive region 33 and a portion of the first drain electrode 22 not covered by the second conductive region 33, and therefore, the second source electrode 71 is simultaneously connected to the first source electrode 21 and the first source electrode 21 and a first conductive region 32, and the second drain electrode 72 is electrically connected to the second source electrode 71 and the second drain electrode 72 at the same time.

It can be understood that in other embodiments of the present invention, with reference to FIG. 2, since the first via 61 only corresponds to the first source electrode 21, the second via 62 only corresponds to the second drain electrode 72. Therefore, the second source electrode 71 is only electrically connected to the first source electrode 21, and the second drain electrode 72 is only electrically connected to the first drain electrode 22. Alternatively, with reference to FIG. 3, in another embodiment of the present invention, since the first via 61 extends to the first source electrode 21 through the first conductive region 32, the second via 62 extends to the first drain electrode 22 through the second conductive region 33, so that the second source electrode 71 is electrically connected to the first source electrode 21 through the first conductive layer. The second drain electrode 72 is electrically connected to the first drain electrode 22 through the second conductive layer.

In the present invention, through the first source electrode 21, an electrical connection between the second source electrode 71 and the first conductive region 32 of the semiconductor layer 30 is realized. Through the first drain electrode 22, an electrical connection between the second drain electrode 72 and the second conductive region 33 of the semiconductor layer 30 is realized. Since the first conductive region 32 and the second conductive region 33 are all electrically conductive, a contact impedance between the first conductive region 32 and the first source electrode 21 or the second source electrode 71 is greatly reduced, and a contact impedance between the second conductive region 33 and the first drain electrode 22 or the second drain electrode 72 is greatly reduced in order to ensure the electrical property of the thin film transistor.

Moreover, since a contact area between the first conductive region 32 and the first source electrode 21 is larger than a contact area between the source electrode and the semiconductor layer 30 in the prior art; a contact area between the second conductive region 33 and the first drain electrode 22 is greater than a contact area between the drain electrode and the semiconductor layer 30 in the prior art, that is, a contact impedance between the first conductive region 32 and the first source electrode 21 is reduced comparing to a contact impedance between the source electrode and the semiconductor layer 30 in the prior art; a contact impedance between the second conductive region 33 and the first drain electrode 22 is reduced comparing to a contact impedance between the drain electrode and the semiconductor layer 30 in the prior art, the electrical property of the thin film transistor is further enhanced.

In addition, the second source-drain layer 70 is formed of a metal material, and the material for forming the second source-drain layer 70 may be metal molybdenum, metal aluminum or metal copper. In this embodiment, the material of the second source-drain layer 70 is the same as the first source-drain layer 20 to reduce a contact resistance between the second source electrode 71 and the first source and a contact resistance between the second drain electrode 72 and the first drain electrode 22 as much as possible in order to enhance the electrical performance of the thin film transistor.

Furthermore, a passivation layer 80 and a pixel electrode layer 90 are further formed on the second source-drain layer 70. The passivation layer 80 covers the second source-drain layer 70. The pixel electrode layer 90 includes multiple pixel electrodes arranged as a matrix. The pixel electrode is electrically connected to the second source electrode 71 or the second drain electrode 72 of the second source-drain layer 70 through vias.

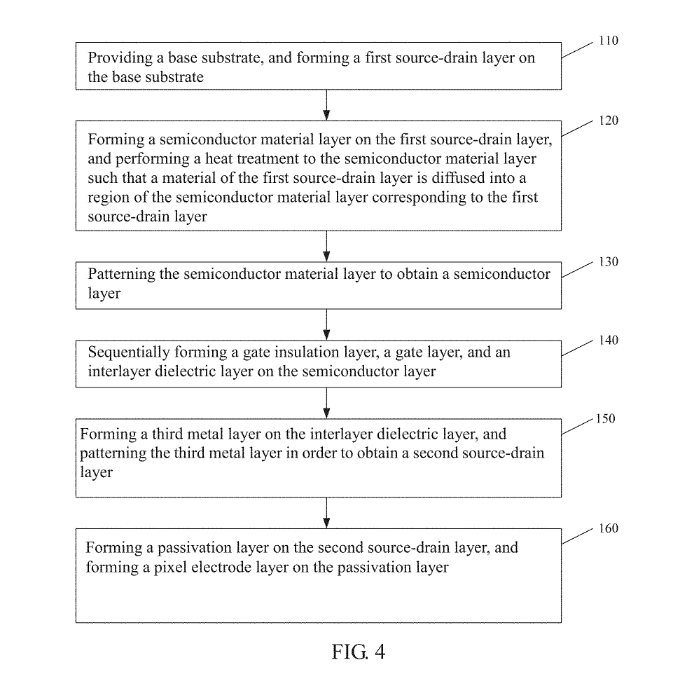

With reference to FIG. 4, the present further provides a manufacturing method for an array substrate. In the present embodiment, an array substrate 100 is obtained through the manufacturing method for the array substrate 100. The method includes steps of:

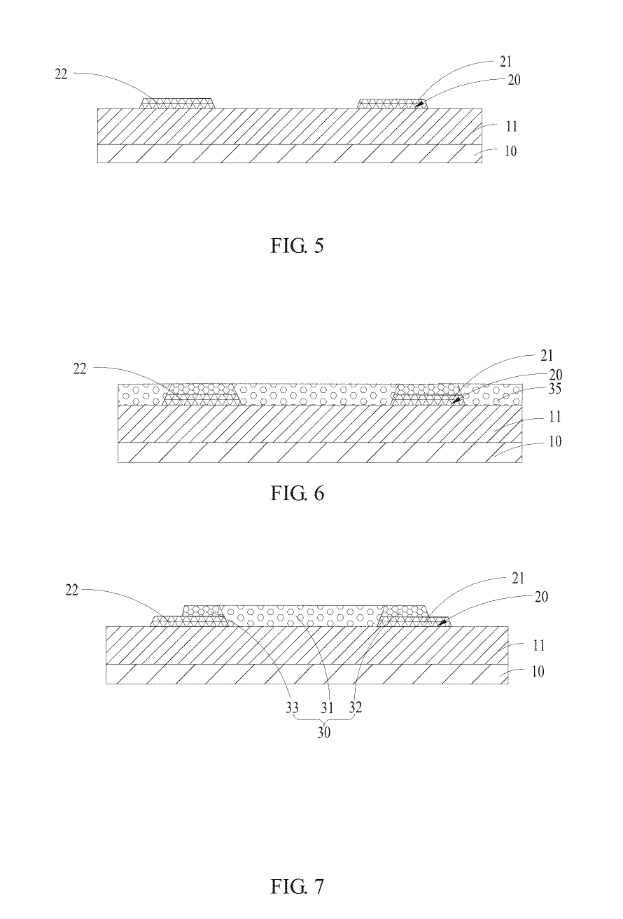

In a step 110, referring to FIG. 5, providing a base substrate 10, and forming a first source-drain layer 20 on the base substrate 10.

Specifically, providing a base substrate 10, depositing a first metal material layer on the base substrate 10, and patterning the first metal material layer to obtain the first source-drain layer 20. In addition, in the present embodiment, before the step of depositing a first metal material layer on the base substrate 10, forming a buffer layer 11 through a coating or a transferring method, then, depositing the first metal material layer on the buffer layer 11 though a sputtering or a vapor deposition. Patterning the first metal material layer through exposure, development, etching in order to obtain the first source-drain layer 20, and the first source-drain layer 20 includes a first source electrode 21 and a first drain electrode 22 which are disposed separately.

In a step 120, referring to FIG. 6, forming a semiconductor material layer 35 on the first source-drain layer 20, and performing a heat treatment to the semiconductor material layer 35 such that a material of the first source-drain layer 20 is diffused into a region of the semiconductor material layer 35 corresponding to the first source-drain layer 20, and the oxygen content in the semiconductor material layer 35 is redistributed so that the region of the semiconductor material layer 35 corresponding to the first source-drain layer 20 becomes conductive. The conductive region obtained by this method has a good thermal stability, can be kept stable in the subsequent heat treatment process, and the conductive state is not easily changed. In the present embodiment, the heat treatment of the semiconductor material layer 35 is an annealing treatment, and the annealing temperature is 280° C.˜320° C.

In a step 130, referring to FIG. 7, patterning the semiconductor material layer 35 to obtain a semiconductor layer 30.

Patterning the semiconductor material layer 35 through exposure, development, and etching to obtain the semiconductor layer 30. The semiconductor layer 30 includes a semiconductor region 31, a first conductive region 32 and a second conductive region 33. The first conductive region 32 and the second conductive region 33 are located at two sides of the semiconductor region 31 and are respectively connected to the semiconductor region 31. The first conductive region 32 is stacked on the first source electrode 21, and the second conductive region 33 is stacked on the first drain electrode 22.

In a step 140, sequentially forming a gate insulation layer 40, a gate layer 50, and an interlayer dielectric layer 60 on the semiconductor layer 30.

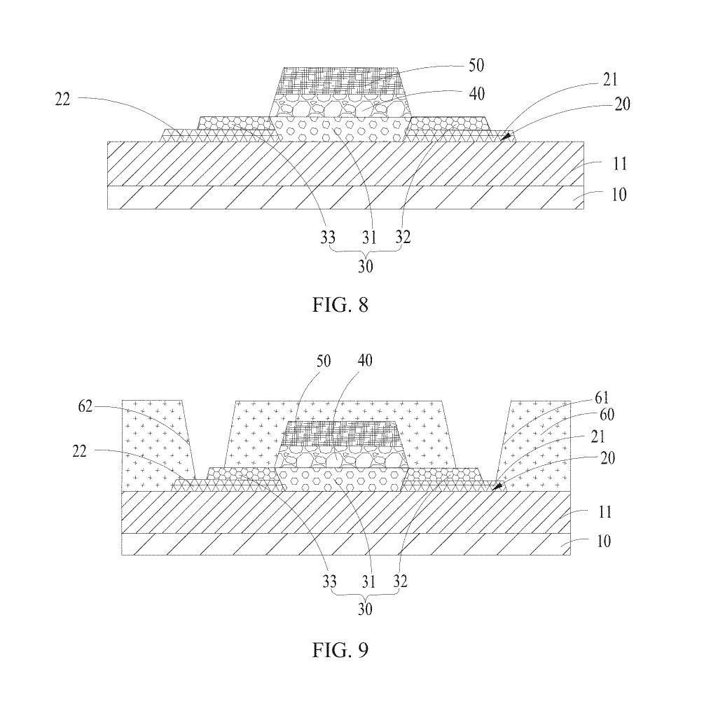

Specifically, referring to FIG. 8, the gate insulating material layer is formed on the semiconductor layer 30 by a process such as coating or transferring, and then, depositing a second metal layer on the gate insulation material layer through sputtering or vapor deposition. Patterning the gate insulation material layer and the second metal layer are through exposure, development, and etching in order to obtain a gate insulation layer 40 and a gate layer 50. Afterwards, referring to FIG. 9, the interlayer dielectric material layer is formed on the gate layer 50 through coating or transferring. Forming a first via 61 and a second via 62 on the interlayer dielectric material layer by a patterning process such as exposure, development, and etching in order to obtain the interlayer dielectric layer 60.

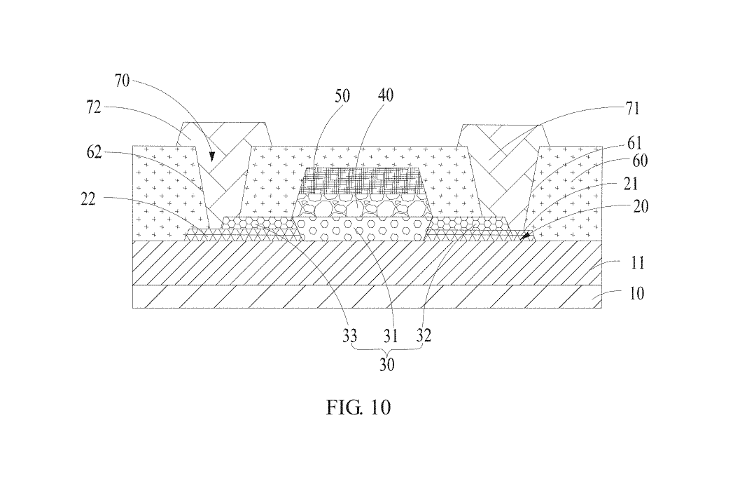

In a step 150, referring to FIG. 10, forming a second source-drain layer on the interlayer dielectric layer 60. Specifically, forming a third metal layer on the interlayer dielectric layer 60, and patterning the third metal layer in order to obtain the second source-drain layer 70. The second source-drain layer 70 includes a second source electrode 71 and a second drain electrode 72 which are disposed separately, and the second source electrode 71 is electrically connected to the first source electrode 21 through the first via 61. The second drain electrode 72 is electrically connected to the first drain electrode 22 through the second via 62.

In a step 160, referring again to FIG. 1, forming a passivation layer 80 on the second source-drain layer 70, and forming a pixel electrode layer 90 on the passivation layer 80. The pixel electrode layer 90 includes multiple pixel electrodes arranged as a matrix, and the pixel electrode is electrically connected to the second source-drain layer 70 through a via.

In the array substrate 100 and the manufacturing method for the array substrate 100 provided in the present invention, through forming a first source-drain layer 20 between the base substrate and the semiconductor material layer 30, and performing a heat treatment to the semiconductor layer 30 before patterning the semiconductor material layer 35 such that a material of the first source-drain layer 20 is diffused into a region of the semiconductor material layer 35, and the oxygen content in the semiconductor material layer 35 is redistributed such that a region of the semiconductor material layer 35 corresponding to the first source-drain layer 20 becomes conductive in order to obtain a first conductive region 32 and a second conductive region 33. The first conductive region and the second conductive region have a good thermal stability, without being affected by subsequent heat treatment. Besides, the first conductive region 32 is stacked on the first source electrode 21, and the second conductive region 33 is stacked on the first drain electrode 22, that is, when the second source electrode 71 and the first source electrode 21 are electrically connected, the second source electrode 71 is electrically connected to through the first conductive region 32 through the first source electrode. The second conductive region 33 is electrically connected to the first drain electrode 22. Because both the first conductive region 32 and the second conductive region 33 become conductive and are not affected by the subsequent heat treatment process, so that the contact resistance between the source and drain electrodes and the semiconductor layer 30 is reduced, and the contact resistance is not affected by the subsequent heat treatment process so as to ensure carrier transport and ensure the electrical properties of the thin film transistor.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An array substrate, comprising:
a base substrate;
a first source-drain layer, a semiconductor layer, gate insulation layer, a gate layer, interlayer dielectric layer, and a second source-drain layer which are sequentially stacked on the base substrate;
wherein the first source-drain layer includes a first source electrode and a first drain electrode which are disposed separately;
wherein the semiconductor layer includes a semiconductor region, a first conductive region, and a second conductive region; the first conductive region and the second conductive region are respectively located at two sides of the semiconductor region and are connected to the semiconductor region; the first conductive region is stacked on the first source electrode, and the second conductive region is stacked on the first drain electrode; the first conductive region and the second conductive region are both obtained by diffusing a material of the first source-drain layer into the semiconductor layer;
wherein the second source-drain layer includes a second source electrode and a second drain electrode which are disposed separately; and
wherein the second source electrode is electrically connected to the first source electrode through a first via; the second drain electrode is electrically connected to the first drain electrode through a second via.

2. The array substrate according to claim 1, wherein the first conductive region partially covers the first source electrode, and the second conductive region partially covers the first drain electrode; the first via corresponds to a portion of the first conductive region and a portion of the first source electrode not covered by the first conductive region; the second via corresponds to a portion of the second conductive region and a portion of the first drain electrode not covered by the second conductive region.

3. The array substrate according to claim 1, wherein the first conductive region partially covers the first source electrode, and the second conductive region partially covers the first drain electrode; the first via corresponds to a location of the first conductive region not covered by the first source electrode, and the second via corresponds to a location of the second conductive region not covered by the first drain electrode.

4. The array substrate according to claim 1, wherein the gate layer includes a gate electrode, the gate electrode layer is stacked on the gate insulation layer, and an orthographic projection of the gate insulation layer and the gate electrode on the semiconductor layer is located within the semiconductor region.

5. The array substrate according to claim 1, wherein the material of the first source-drain layer is a metal material having a work function less than 4.4 ev and a resistivity less than 10⁻⁷ Ω·m.

6. The array substrate according to claim 5, wherein the material of the second source-drain layer is aluminum.

7. A manufacturing method for an array substrate, comprising steps of:
providing a base substrate, and forming a first source-drain layer on the base substrate, wherein the first source-drain layer includes a first source electrode and a first drain electrode disposed separately;
forming a semiconductor material layer on the first source-drain layer, performing a heat treatment to the semiconductor material layer such that a material of the first source-drain layer is diffused into a region of the semiconductor material layer corresponding to the first source-drain layer, and the region of the semiconductor material layer corresponding to the first source-drain layer becomes conductive;
patterning the semiconductor material layer to obtain a semiconductor layer, wherein the semiconductor layer includes a semiconductor region, a first conductive region and a second conductive region, the first conductive region and the second conductive region are located at two sides of the semiconductor region and are respectively connected to the semiconductor region, the first conductive region is stacked on the first source electrode, and the second conductive region is stacked on the first drain electrode;
sequentially forming a gate insulation layer, a gate layer, and an interlayer dielectric layer on the semiconductor layer;
forming a second source-drain layer on the interlayer dielectric layer, wherein the second source-drain layer includes a second source electrode and a second drain electrode which are disposed separately, the second source electrode is electrically connected to the first source electrode through a first via; the second drain electrode is electrically connected to the first drain electrode through a second via.

8. The manufacturing method for an array substrate according to claim 7, wherein the method further comprises steps of: forming a passivation layer on the second source-drain layer, and forming a pixel electrode layer on the passivation layer, wherein the pixel electrode layer includes multiple pixel electrodes arranged as a matrix, and the pixel electrode is electrically connected to the second source-drain layer through a via.

9. The manufacturing method for an array substrate according to claim 7, wherein the step of performing a heat treatment to the semiconductor material layer is to perform an annealing treatment to the semiconductor material layer.

10. The manufacturing method for an array substrate according to claim 7, wherein the material of the first source-drain layer is a metal material having a work function less than 4.4 ev and a resistivity less than 10⁻⁷ Ω·m.
